(19) United States
(12) Patent Application Publication
(10) Pub. No.: US 2016/0284883 A1
(43) Pub. Date: Sep. 29, 2016

(54) SOLAR CELL WITH REAR SIDE MULTI-LAYER ANTI-REFLECTION COATING

(71) Applicant: NEO SOLAR POWER CORP., Hsinchu (TW)

(72) Inventors: Shr-Han Feng, New Taipei City (TW); Chia-Pang Kuo, Kaohsiung City (TW)

(21) Appl. No.: 15/000,037

(22) Filed: Jan. 19, 2016

(30) Foreign Application Priority Data
Mar. 26, 2015 (TW) 104109774

(51) Int. Cl. H01L 31/0216

(52) U.S. Cl. CPC H01L 31/02168; H01L 31/02167

(57) ABSTRACT

A solar cell includes a semiconductor substrate with a first surface and a second surface, a doped emitter layer on the first surface, at least one front anti-reflection coating (ARC) on the first surface, a front electrode on the front ARC, a passivation layer on the second surface, a first rear ARC on the passivation layer, a second rear ARC on the first rear ARC, a third rear ARC on the second rear ARC, and a rear electrode on the third rear ARC. The first rear ARC has a refractive index that is smaller than 2.1, while the second rear ARC has a refractive index that is greater than or equal to 2.1. The second rear ARC has a refractive index that is greater than that of the third rear ARC.

### CROSS REFERENCE TO RELATED APPLICATION

This application claims priority from Taiwan Patent application Ser. No. 104109774, filed Mar. 26, 2015.

### BACKGROUND OF THE INVENTION

1. Field of the Invention

The present invention relates generally to the field of solar cell technology. More specifically, the present invention relates to a passivated emitter and rear cell (PERC) having rear-side multi-layer anti-reflection coating (ARC).

2. Description of the Prior Art

A solar cell is an electrical device that converts the energy of light directly into electricity by the photovoltaic effect. The light incident into the semiconductor substrate of the solar cell generates electron-hole pairs at the PN junction. Before they are recombined, the electrons and holes are collected by the cell front electrode on light-receiving surface and rear electrode, respectively, thereby generating photocurrent.

As known in the art, a passivated emitter and rear cell (PERC) takes advantage of the passivation layer (usually a thin aluminum oxide layer) formed on the rear surface of the solar cell to reduce the recombination of electron-hole pairs, and typically uses an anti-reflective coating (ARC) to reflect light back to the solar cell to improve the cell efficiency.

There is still a need for an improved anti-reflection coating structure, with the passivation layer on the rear surface of the solar cell, which is suitable for the PERC applications, to further improve the efficiency.

### SUMMARY OF THE INVENTION

To these ends, one aspect of the present invention is a solar cell including a semiconductor substrate with a first surface and a second surface, a doped emitter layer on the first surface, at least one front anti-reflection coating (ARC) on the first surface, a front electrode on the front ARC, a passivation layer on the second surface, a first rear ARC on the passivation layer, a second rear ARC on the first rear ARC, a third rear ARC on the second rear ARC, and a rear electrode on the third rear ARC. The first rear ARC has a refractive index that is smaller than 2.1, while the second rear ARC has a refractive index that is greater than or equal to 2.1. The second rear ARC has a refractive index that is greater than that of the third rear ARC.

Other objects, features, and advantages of the present invention will be apparent from the company drawings and from the following detailed description.

### BRIEF DESCRIPTION OF THE DRAWINGS

FIG. 1 is a schematic, cross-sectional diagram showing a portion of a solar cell according to one embodiment of the invention.

FIG. 2 shows an example of the rear electrode of the solar cell according to one embodiment of the invention.

FIG. 3 shows an example of the rear electrode of the solar cell according to another embodiment of the invention.

FIG. 4 shows an example of the rear electrode of the solar cell according to still another embodiment of the invention.

### DETAILED DESCRIPTION

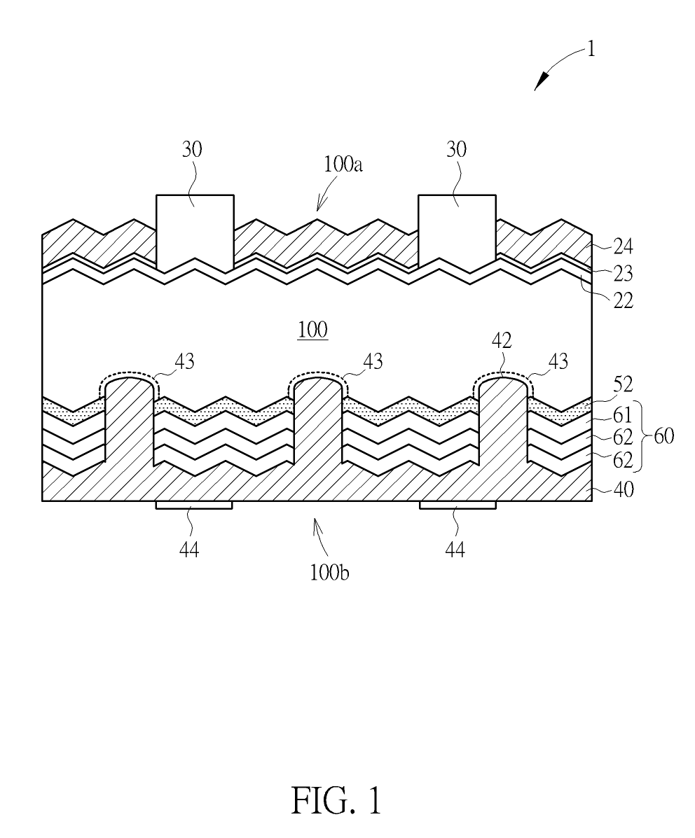

Please refer to FIG. 1. FIG. 1 is a schematic, cross-sectional diagram showing a portion of a solar cell according to one embodiment of the invention. As shown in FIG. 1, the solar cell 1 includes a semiconductor substrate 100 with a first surface 100a and a second surface 100b that is opposite to the first surface 100a.

According to the embodiment, the semiconductor substrate 100 may be an N-type or P-type single-crystalline silicon substrate or poly-crystalline silicon substrate, but not limited thereto. The first surface 100a and the second surface 100b may be subjected to a surface roughness (texturing) treatment to form uneven structures.

According to the embodiment, the first surface 100a includes an N-type or P-type doped emitter layer 22 which formed by diffusion or anoy other doping process, an oxide layer 23 such as a silicon dioxide layer, and at least one front anti-reflection coating (ARC) 24. According to the embodiment, the doped emitter layer 22 has a conductivity type that is opposite to the semiconductor substrate 10. For example, the semiconductor substrate 100 is a P-type single-crystalline silicon substrate and the doped emitter layer 22 is N-type. The doped emitter layer 22 may be a conventional doped emitted layer known in the art, or may be a selective emitter. The oxide layer 23 has a thickness ranging between 5 nm and 10 nm, preferably, 7 nm. The oxide layer 23 is able to increase surface passivation of the single-crystalline silicon substrate thereby reducing Potential Induced Degradation (PID). In other embodiments, when the semiconductor substrate 100 is a poly-crystalline silicon substrate, the oxide layer 23 may be omitted from the surface of the doped emitter layer 22. According to the embodiment, the front ARC 24 may include silicon nitride, but not limited thereto.

According to the embodiment, at least one front electrode 30 is provided on the first surface 100a. For example, a screen printing method may be performed to dispose conductive paste material on the first surface 100a of the solar cell 1. The conductive paste material is then subjected to a firing process to form the front electrode 30. After the firing process, the front electrode 30 penetrates through the front ARC 24 to directly contact the doped emitter layer 22. In other embodiments, the front ARC 24 is a patterned anti-reflection coating film. The aforesaid conductive paste material is in contact with the doped emitter layer 22 through the pattern in the front ARC 24 and is fired to form the front electrode 30. The aforesaid pattern in the front ARC 24 means at least one opening extending through the entire thickness of the front ARC 24.

According to the embodiment, a rear electrode 40 and a rear contact electrode 44 are provided on the second surface 100b. According to the embodiment, the rear electrode 40 includes aluminum and the rear contact electrode 44 includes silver, aluminum, or other metals, but not limited thereto. A passivation layer 52, for example, aluminum oxide (AlOx) layer, is disposed between the rear electrode 40 and the semiconductor substrate 100. The passivation layer 52 has a thickness ranging between 1 and 20 nanometers and a refractive index ranging between 1.6 and 1.7 inclusive. The passivation layer 52 has at least a first opening that exposes a portion of the second surface 100b. The rear electrode 40 including aluminum extends into the first opening and forms an aluminum silicon alloy layer 42 within the first opening. A local back surface field (local BSF) 43 is formed at the interface between the aluminum silicon alloy layer 42 and the semiconductor substrate 100. The aforesaid first opening may be a continuous or a discontinuous opening, a line-shape opening, a dashed line-shaped opening, or a dotted line-shaped opening, but not limited thereto.

The multi-layer anti-reflection coating (ARC) 60 disposed between the rear electrode 40 and the passivation layer 52. According to the embodiment, the multi-layer ARC 60 includes a first rear ARC 61, a second rear ARC 62, and a third ARC 63. The first rear ARC 61 is directly disposed on the passivation layer 52 and is in direct contact with the first rear ARC 61. The second rear ARC 62 is directly disposed on the first rear ARC 61 and is in direct contact with the first rear ARC 61. The third rear ARC 63 is directly disposed on the second rear ARC 62 and is in direct contact with the second ARC 62. The rear electrode 40 is directly disposed on the third rear ARC 63 and is in direct contact with the third rear ARC 63.

According to the embodiment, the first rear ARC 61 has a second opening corresponding to the aforesaid first opening, the second rear ARC 62 has a third opening corresponding to the second opening, and the third rear ARC 63 has a fourth opening corresponding to the third opening. The rear electrode 40 contacts the semiconductor substrate 100 through the first opening, the second opening, the third opening, and the fourth opening, thereby forming the aluminum silicon alloy layer 42 in the first opening.

According to the embodiment, the first rear ARC 61 has a refractive index smaller than that of the second rear ARC 62. For example, the first rear ARC 61 is a silicon nitride (SiNx) film having a thickness ranging between 20 nm and 70 nm and a refractive index smaller than 2.1, for example, between 1.95 and 2.1. The second rear ARC 62 is a silicon nitride film having a thickness ranging between 5 nm and 10 nm and a refractive index that is equal to or greater than 2.1, for example, between 2.1 and 2.35 inclusive. The third rear ARC 63 is a silicon nitride film having a thickness ranging between 45 nm and 145 nm and a refractive index that is smaller than that of the second ARC 62, for example, a refractive index smaller than 2.1, preferably, 2.01. Since the second rear ARC 62 of the aforesaid multi-layer ARC 60 has a refractive index that is greater than that of the third ARC 63, a portion of the light incident into the first surface 100a may be reflected at the interface between the second ARC 62 and the third ARC 63, thereby improving the utilization of the light incident into the first surface 100a. Further, in order to prevent excess light absorption of the second ARC 62 that reduces the utilization of light, the second ARC 62 preferably has a thickness ranging between 5 nm and 10 nm, more preferably, 7 nm. In order to prevent damage to the first ARC 61, the second ARC 62, or the passivation layer 52 resulted from the penetration of the rear electrode 40 through the third ARC 63, the third ARC 63 preferably has a thickness of at least 45 nm, more preferably, between 45 nm and 145 nm.

According to another embodiment of the invention, the first rear ARC 61 is a silicon oxynitride film having a thickness ranging between 20 nm and 70 nm and a refractive index smaller than 2.1, for example, between 1.5 and 1.9, preferably, 1.7. The second rear ARC 62 is a silicon nitride film having a thickness of about 5 nm and a refractive index that is equal to or greater than 2.1, for example, between 2.1 and 2.35 inclusive, preferably, 2.15. The third rear ARC 63 is a silicon nitride film having a thickness ranging between 45 nm and 145 nm and a refractive index that is smaller than that of the second ARC 62, for example, a refractive index smaller than 2.1, preferably, 2.01.

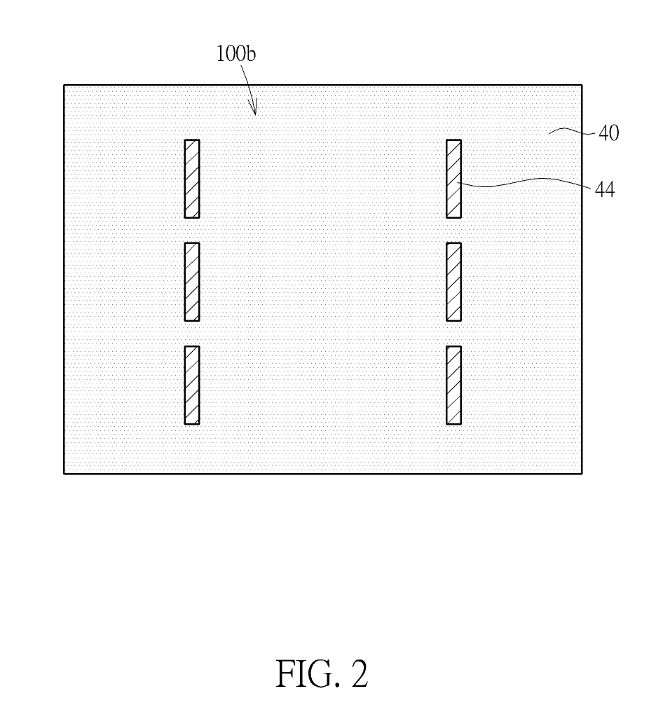

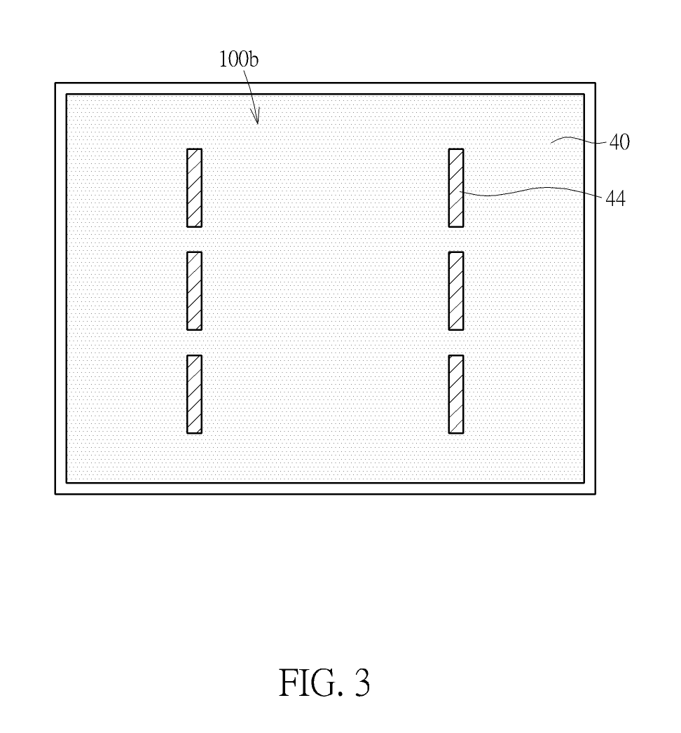

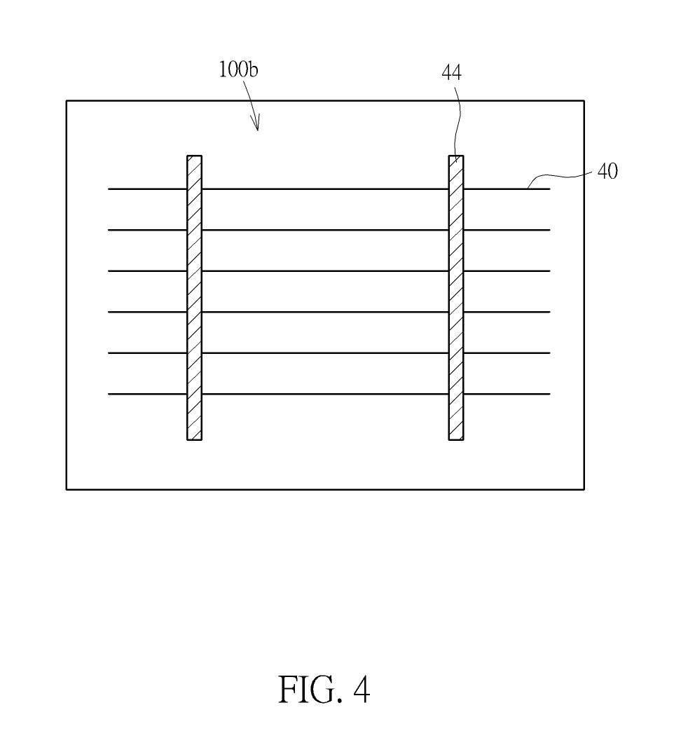

FIGS. 2-4 illustrate some examples of the rear electrode of the solar cell according to the invention. The rear electrode 40 may completely cover the second surface 100b, as shown in FIG. 2. Another embodiment of the invention, the rear electrode 40 may partially cover the second surface 100b, as shown in FIG. 3. Another embodiment of the invention, the rear electrode 40 of the solar cell may be multiple stripes and covers a portion of the second surface 100b, which allows light pass through the areas not covered by the rear electrode 40 or rear contact electrode 44 and enter the solar cell, as shown in FIG. 4.

By providing the multi-layer ARC 60 between the rear electrode 40 and the passivation layer 52, a better reflection at the rear surface of the solar cell can be achieved. The increased internal light reflection can improve battery efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar cell, comprising:
a semiconductor substrate having a first surface and a second surface;
a doped emitter layer on the first surface;
at least one front anti-reflection coating (ARC) on the first surface;
a front electrode on the front ARC and penetrating through the front ARC to contact the doped emitter layer;
a passivation layer disposed on the second surface;
a first rear ARC disposed on the passivation layer;
a second rear ARC disposed on the first rear ARC;
a third rear ARC disposed on the second rear ARC; and
a rear electrode on the third rear ARC. The first rear ARC has a refractive index that is smaller than 2.1, while the second rear ARC has a refractive index that is greater than or equal to 2.1, wherein the second rear ARC has a refractive index that is greater than that of the third rear ARC.

2. The solar cell according to claim 1, wherein the semiconductor substrate has a first conductivity type, the doped emitter layer has a second conductivity type, and the first conductivity type is opposite to the second conductivity type.

3. The solar cell according to claim 1, wherein the passivation layer is an aluminum oxide layer.

4. The solar cell according to claim 3, wherein the passivation layer has a thickness ranging between 1 and 20 nanometers and a refractive index ranging between 1.6 and 1.7 inclusive.

5. The solar cell according to claim 1, wherein the first rear ARC is a silicon oxynitride film.

6. The solar cell according to claim 5, wherein the first rear ARC has a refractive index ranging between 1.5 and 1.9 inclusive.

7. The solar cell according to claim 6, wherein the second rear ARC is a silicon nitride film.

8. The solar cell according to claim 7, wherein the second rear ARC has a refractive index ranging between 2.1 and 2.35 inclusive.

9. The solar cell according to claim 1, wherein the third ARC is a silicon nitride film.

10. The solar cell according to claim 9, wherein the third ARC has a refractive index smaller than 2.1.

11. The solar cell according to claim 8, wherein the third ARC is a silicon nitride film.

12. The solar cell according to claim 11, wherein the third ARC has a refractive index smaller than 2.1.
